(19) United States
(12) Patent Application Publication
(10) Pub. No.: US 2019/0265281 A1
(43) Pub. Date: Aug. 29, 2019

(54) ELECTRIC POWER MANAGEMENT SYSTEM AND METHOD

(71) Applicants: LUCIS TECHNOLOGIES (SHANGHAI) CO., LTD., Shanghai (CN); LUCIS TECHNOLOGIES HOLDINGS LIMITED, Grand Cayman (KY)

(72) Inventors: Kan LI, Shanghai (CN); Defeng SHI, Shanghai (CN); Shan GUAN, FREMONT, CA (US)

(73) Assignees: LUCIS TECHNOLOGIES (SHANGHAI) CO., LTD., Shanghai (CN); LUCIS TECHNOLOGIES HOLDINGS LIMITED, Grand Cayman (KY)

(21) Appl. No.: 16/326,707

(22) PCT Filed: Aug. 19, 2016
(86) PCT No.: PCT/CN2016/096097

§ 371 Date: May 9, 2019

(51) Int. Cl. G01R 21/06; G01R 19/02; G01R 22/10

(52) U.S. Cl. CPC G01R 21/06; G01R 22/10; G01R 19/02

(57) ABSTRACT

The present disclosure provides a system and method for calculating electrical power. The method may include one or more operations of the following operations. Obtaining one or more current values. Setting a first voltage value. Generating one or more second voltage values based on the first voltage value. The one or more second voltage values may correspond to the one or more current values, respectively. Generating one or more first power values according to the one or more current values and the one or more second voltage values.

### TECHNICAL FIELD

The present disclosure relates to methods and systems for managing electric circuits, and more particularly, relates to methods and systems for controlling and calculating electric power in electric circuits.

### BACKGROUND

With the development of society, more and more attention has been paid on smart home systems. The smart home systems reflect an internet of everything (IoE) under the influence of the Internet. A smart home system connects various devices (e.g., an audio equipment, a video equipment, a lighting system, a security system, a digital cinema system, an audio server, a video server, a network household appliance, etc.) in a home through an Internet of Things (IoT) for facilitating household appliance controlling, lighting controlling, telephone remote controlling, indoor and/or outdoor remote controlling, heating, ventilation and air condition (HVAC) controlling, programmable timing controlling, or the like.

The smart home systems may use microprocessors to connect and control each appliance, for example, measure an electric power value of the each appliance. Existing power meters may usually use different elements to measure instantaneous voltage values and instantaneous current values, respectively, in an electric circuit to obtain the electric power value. To measure power values of multiple household appliances, a large number of elements may be required, which may result in a complex electric circuit, as well as increase the cost of installation and maintenance. Therefore, a more concise and effective intelligent circuit management method and system may be needed so as to realize the monitoring and controlling of electrical appliances.

### SUMMARY

According to an aspect of the present disclosure, a system may be provided. The system may include an acquisition unit, an input unit, and a calculating unit. The acquisition unit may obtain one or more current values. The input unit may set a first voltage value. The calculating unit may generate one or more second voltage values according to the first voltage value. The one or more second voltage values may correspond to the one or more current values, respectively. The calculating unit may generate one or more first power values according to the one or more current values and the one or more second voltage values.

Some embodiments of the present disclosure provide a method. The method may include one or more of the following operations. One or more current values may be obtained. A first voltage value may be set. One or more second voltage values may be generated based on the first voltage value. The one or more second voltage values may correspond to the one or more current values, respectively. One or more first power values according to the one or more current values and the one or more second voltage values may be generated.

Some embodiments of the present disclosure may provide a computer readable storage medium for storing executable instructions. The executable instructions may cause a computer device to perform one or more of the following operations. One or more current values may be obtained. A first voltage value may be set. One or more second voltage values may be generated based on the first voltage value. The one or more second voltage values may correspond to the one or more current values, respectively. One or more first power values may be generated according to the one or more current values and the one or more second voltage values. In some embodiments, the one or more current values may be obtained at one or more time points. In some embodiments, intervals between the one or more time points may be equal.

In some embodiments, the first voltage value may be a standard value.

In some embodiments, the one or more first power values may be products of the one or more current values and the one or more second voltage values, respectively.

In some embodiments, a second power value may be further generated according to one or more first power values.

In some embodiments, the second power value may be obtained based on the one or more first power value and an averaging algorithm.

Additional features will be set forth in part in the description which follows, and in part will become apparent to those skilled in the art upon examination of the following and the accompanying drawings or may be learned by production or operation of the examples. The features of the present disclosure may be realized and attained by practice or use of various aspects of the methodologies, instrumentalities, and combinations set forth in the detailed examples discussed below.

### BRIEF DESCRIPTION OF THE DRAWINGS

In order to illustrate the technical solutions related to the embodiments of the present disclosure, a brief introduction of the drawings referred to the description of the embodiments is provided below. Obviously, drawings described below are only some examples or embodiments of the present disclosure. Those having ordinary skills in the art, without further creative efforts, may apply the present disclosure to other similar scenarios according to these drawings. Unless stated otherwise or obvious from the context, the same reference numeral in the drawings refers to the same structure and operation.

FIG. 1 is a schematic diagram of an exemplary system configuration of a circuit management system according to some embodiments of the present disclosure;

FIG. 2 is a schematic diagram of a circuit control terminal according to some embodiments of the present disclosure;

FIG. 3 is an exemplary flowchart of a circuit control terminal according to some embodiments of the present disclosure;

FIG. 4 is a schematic diagram of an acquisition module according to some embodiments of the present disclosure;

FIG. 5 is a schematic diagram of a processing module according to some embodiments of the present disclosure;

FIG. 6 is a flowchart of an exemplary process for processing obtained information and generating a control instruction according to some embodiments of the present disclosure;

FIG. 7 is a flowchart of an exemplary process for calculating an instantaneous power according to some embodiments of the present disclosure;

FIG. 8 is a schematic diagram illustrating the calculation of an instantaneous voltage according to some embodiments of the present disclosure;

FIG. 9 is a flowchart of an exemplary process for calculating effective power in a cycle according to some embodiments of the present disclosure;

FIG. 10 is a schematic diagram illustrating operation sequences of an acquisition unit and a calculating unit according to some embodiments of the present disclosure; and

FIG. 11 is a flowchart of an exemplary process for calculating average power according to some embodiments of present disclosure.

### DETAILED DESCRIPTION OF THE DRAWINGS

As used in the disclosure and the appended claims, the singular forms “a,” “an,” and “the” may include plural referents unless the content clearly dictates otherwise. The terms “including” and “comprising” are merely meant to include the steps and elements that are specifically identified, and such steps and elements may not constitute an exclusive list, and the method or device may also include other steps or elements. The term “based on” may be “based at least in part on.” The term “one embodiment” may mean “at least one embodiment”. The term “another embodiment” may mean “at least one additional embodiment.” The relevant definitions of other terms will be given in the description below.

Some modules of the system may be referred to in various ways according to some embodiments of the present disclosure, however, any number of different modules may be used and operated in a client terminal and/or a server. These modules are intended to be illustrative, and not intended to limit the scope of the present disclosure. Different modules may be used in different aspects of the system and method.

According to some embodiments of the present disclosure, flowcharts may be used to illustrate the operations performed by the system. It should be understood that the operations above or below may or may not be implemented in order. Conversely, the operations may be performed in inverted order, or simultaneously. Besides, one or more other operations may be added to the flowcharts, or one or more operations may be omitted from the flowchart.

The system and method described in the present disclosure are related to systems and methods described in International Patent Application No. PCT/CN2015/075923, entitled “ENVIRONMENTAL CONTROL SYSTEM,” filed on Apr. 3, 2015, International Patent Application No. PCT/CN2015/080160, entitled “ENVIRONMENTAL CONTROL SYSTEM,” filed on May 29, 2015, International Patent Application No./(Attorney Docket No. P1B165270PCT), entitled “SYSTEM AND METHOD FOR CONTROLLING APPLIANCES,” International Patent Application No./(Attorney Docket No. P1B165271PCT), entitled “CONTROL SYSTEM,” and International Patent Application No./(Attorney Docket No. P1B165273PCT), entitled “ANTI-INTERFERENCE WIRELESS TRANSCEIVING SYSTEM,” filed on the same day as the present application, the contents of each of which are hereby incorporated by reference.

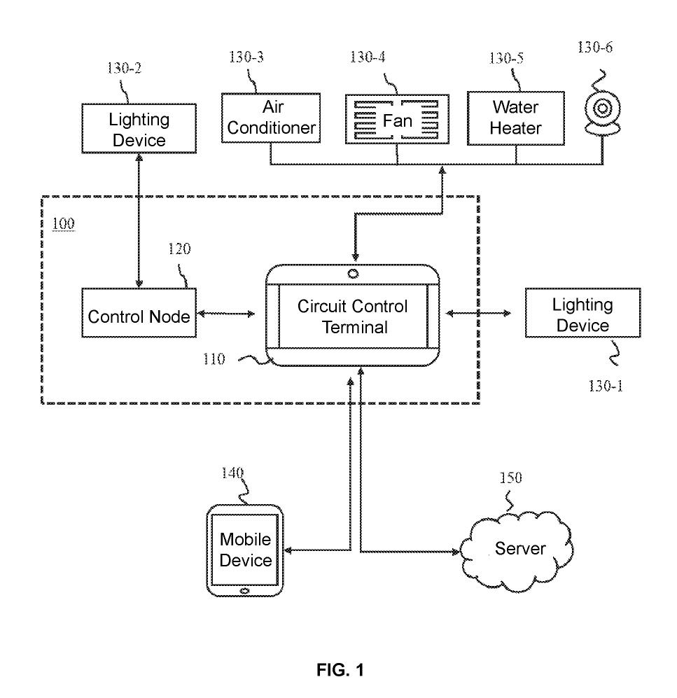

FIG. 1 is a schematic diagram of an exemplary system configuration of a circuit management system according to some embodiments of the present disclosure. The circuit management system 100 may include a circuit control terminal 110, and one or more control nodes 120. The circuit control terminal 110 may control one or more load devices 130. In some embodiments, the circuit control terminal 110 may connect and control the one or more load devices 130 in the circuit directly or indirectly, such as lighting devices 130-1 and 130-2, an air conditioner 130-3, a fan 130-4, a water heater 130-5, a monitoring equipment 130-6, etc.

The control of the load devices 130 by the circuit control terminal 110 may be implemented by the control nodes 120. The control nodes 120 may connect to the circuit control terminal 110, and control one or more devices of the load devices 130-1 through 130-6 in the circuit. In some embodiments, the circuit control terminal 110 may be installed in a living room, and the control nodes 120 may be installed in other rooms, such as a kitchen, a dining room, a bathroom, or the like. In some embodiments, a plurality of control nodes 120 may be installed in different rooms to control load devices in each room.

In some embodiments, the load devices 130 may include a variety of electrical appliances, including but not limited to the appliances or devices shown in FIG. 1. Further, the load devices 130 may include LED lamps, incandescent lamps, a television, a computer, a hair dryer, a water dispenser, a motor, a router, a microwave oven, a heater, an air conditioner, a refrigerator, an electric water heater, chargers, rechargeable batteries, or the like.

In some embodiments, a mobile device 140 may be coupled to the circuit management system 100, and establish a communication with the circuit management system 100 via a user interface on the mobile device 140. The mobile device 140 may be any type of electronic devices including, for example, a cell phone, a computer, a tablet, a smart watch, or the like. In some embodiments, a user may input parameters to the circuit management system 100, change settings of the circuit management system 100, read information of the load devices 130 using the circuit management system 100, and implement on-off control of the load devices 130, through the mobile device 140.

In some embodiments, the server 150 may retrieve and store data obtained or generated by the circuit control terminal 110. These data may be real-time data, historical data, or the like. These data may include electric power of the load devices, working states of the load devices, user behaviors, or the like. These data may be used to analyze personal characteristics such as user preferences, habits, or personalities of a user, and predict the user's behaviors in the future. In some embodiments, the circuit management system 100 may retrieve the stored information from the server 150. In some embodiments, the server may be a cloud server.

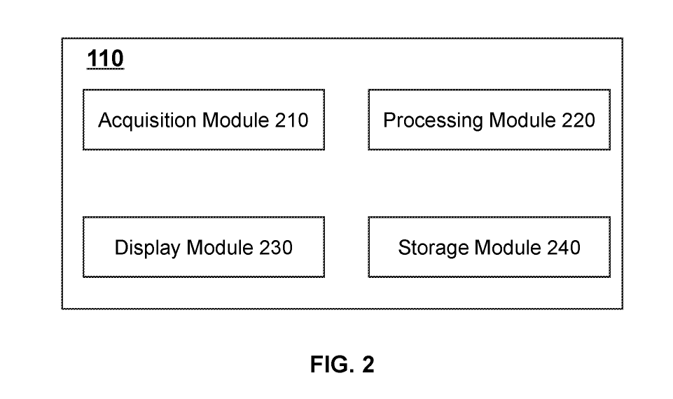

FIG. 2 is a schematic diagram of a circuit control terminal according to some embodiments of the present disclosure. The circuit control terminal 110 may include one or more acquisition modules 210, one or more processing modules 220, one or more display modules 230, and one or more storage modules 240. The connections between modules in the circuit control terminal 110 may be wired connections, wireless connections, or a combination thereof. Each module may be local, remote, or a combination of both.

The acquisition module 210 may mainly be used to obtain an external signal or receive information input by a user. Further, the acquisition module 210 may send the obtained signal or information to the processing module 220 for processing or to the storage module 240 for storing. In some embodiments, the acquisition module 210 may receive a signal or an information acquisition instruction from the processing module 220, and perform a corresponding signal acquisition operation or an input operation. In some embodiments, the acquisition module 210 may obtain a signal of an external circuit, and transmit the signal to the processing module 220 so as to calculate a target parameter. For example, the acquisition module 210 may obtain a voltage value and a current value of a circuit, and send the obtained data to the processing module 220 for further processing or calculating. In some embodiments, the acquisition module 210 may receive an instruction or data input by the user through a user interface of the mobile device 140. In some embodiments, the acquisition module 210 may perform a preprocessing operation on the acquired information.

The processing module 220 may mainly be used for numerical calculation, logical processing, and instruction generation. In some embodiments, the processing module 220 may obtain signals or information from the acquisition module 210 and the storage module 240. Further, the processing module 220 may perform numerical calculation and/or logical processing on the signals or information, and send processed signals or information to the display module 230 or the storage module 240. The processing module 220 may perform a numerical calculation on signals of external circuits received by the acquisition module 210 so as to obtain required target parameters. For example, the processing module 220 may receive electrical parameters such as current, voltage, impedance, and a bias voltage of a load device, and calculate target parameters such as active power, amplification factor, circuit load, and total electricity consumption. In some embodiments, the processing module 220 may perform logical judgment and determination on the calculation results or a user's instructions, thereby generating an executable instruction. For example, the processing module 220 may calculate a total electric power of load devices in a circuit, and compare the total electric power of the load devices with a threshold set by a user. If the total electric power of the load devices is greater than the threshold, the processing module 220 may generate an instruction to shut down or adjust electric powers of a portion or all of the load devices. In some embodiments, the processing module 220 may receive data input by the acquisition module 210 passively, or collect signals or information through the acquisition module 210 according to actual requirements of the user or other modules actively.

The display module 230 may mainly be used to provide the information generated by the processing module 220 to a user. The information to the user provided by the display module 230 may be information related to the circuit or information related to control instructions. In some embodiments, the display module 230 may provide information obtained by the acquisition module 210 to the user directly without any processing. The information provided to the user may include, but not limited to parameter data of an electric circuit (such as voltage, current, impedance, etc.), load condition of the electric circuit, working status of the electric circuit, warning information, instructions to be confirmed generated by the processing module, statistical information based on calculation results or habits of the user. In some embodiments, the display module 230 may provide information in forms of, for example, text, audio, image, or the like, to the user. In some embodiments, the display module 230 may provide information to a user through a physical display, such as a display with a speaker, an LCD, an LED, an OLED, an electronic ink display (E-Ink), or the like. In some embodiments, the display module 230 may receive feedback information. The processing module 220 may generate a corresponding instruction according to the feedback information. For example, the display module 230 may display instruction confirmation information “a total electric power of load devices is quite high. Would you like to turn off a part of the load devices?”. After the user confirms to turn off the part of the load devices, the processing module 220 may generate an instruction to turn off the part of the load devices. In some embodiments, if the mobile device 140 is connected to the circuit control terminal 110, content displayed on the display module 230 may be synchronized to a user interface of the mobile device 140.

The storage module 240 may mainly be used to store information. The storage module 240 may store information received from the acquisition module 210 and the display module 230, transfer the information to the processing module 220 for processing, and store information generated by the processing module 220. Content stored in the storage module 240 may include parameters of external electric circuits collected by the acquisition module 210, control instructions or parameter data input by a user, intermediate data or complete data generated by the processing module 220, and information obtained through the server 150. In some embodiments, the storage module 240 may include but not limited to various types of storage devices, such as a solid state disk, a mechanical hard disk, a USB flash memory, a secure digital (SD) memory card, an optical disk, a random-access memory (RAM), and a read-only memory (ROM), etc. In some embodiments, the storage module 240 may be implemented on a storage device of the circuit management system 100, an external storage device connected to the circuit management system 100, or a network storage device, such as cloud storage implemented on a cloud storage server.

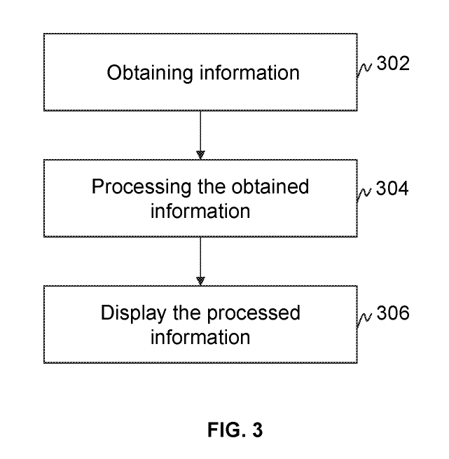

FIG. 3 is an exemplary flowchart of a circuit control terminal according to some embodiments of the present disclosure. The circuit control terminal 110 may obtain information in 302. The information may include electrical parameter values of a circuit or each load device of the load devices 130, information input by a user, or the like. The electrical parameter values may include current values, voltage values, frequency values, etc. collected from the circuit or a load device. The electrical parameter values may be obtained in a direct or indirect manner using corresponding detection elements or devices. For example, an impedance value of an appliance may be calculated based on a current value and a voltage value of the appliance, or acquired using an impedance detection element or device (such as a resistance tester, etc.) directly. The information input by a user may include parameter data, control instructions, or the like. In some embodiments, the circuit control terminal 110 may obtain one or more current values from the circuit or the load devices in the circuit. In some embodiments, the circuit control terminal 110 may obtain a voltage value input by a user.

In 304, the circuit control terminal 110 may process the obtained information. In some embodiments, the circuit control terminal 110 may process the obtained electrical parameter values, parameters input by a user, or the like, using one or more numerical calculation methods. Exemplary processing methods may include a basic operation, analog-to-digital conversion, numerical fitting, or the like. Target parameters such as an average power, a power factor, and an amplification factor of an operational amplifier, etc., may be obtained in the processing. In some embodiments, the circuit control terminal 110 may obtain a power value according to the obtained current value and the voltage value input by the user. In some embodiments, the circuit control terminal 110 may perform an integration operation on the obtained current value and the voltage value input by the user so as to obtain the power value. In some embodiments, the circuit control terminal 110 may obtain a plurality of power values, and obtain an average power value based on the plurality of the power values. In some embodiments, the circuit control terminal 110 may perform a logical judgment on instructions input by a user, and generate an instruction based on the logical judgement. In some embodiments, the circuit control terminal 110 may compare the calculated power value (such as an instantaneous power value, an average power value, etc.) with a preset threshold, and generate an instruction to turn off one or more load devices if the calculated power value is greater than the preset threshold according to an instruction of a user.

In 306, the circuit control terminal 110 may display the processed information. In some embodiments, the processed information may be displayed on the display module 230. The displayed information may include electrical parameter values (such as voltage values, current values, impedance values, etc.) of the load devices, calculated target parameters, working status of the circuit, warning information, instructions generated by the processing module, statistical information based on the calculating results and habits of a user, prediction information regarding behaviors of the user, etc. A manner in which the information is displayed may include but not limited to light, text, audio, image, or the like. In some embodiments, graphic processing and data statistics may be performed on the information to be displayed. For example, power values of a load device in a certain time period may be presented in forms of a table, a histogram, a pie diagram, a bubble diagram, etc.

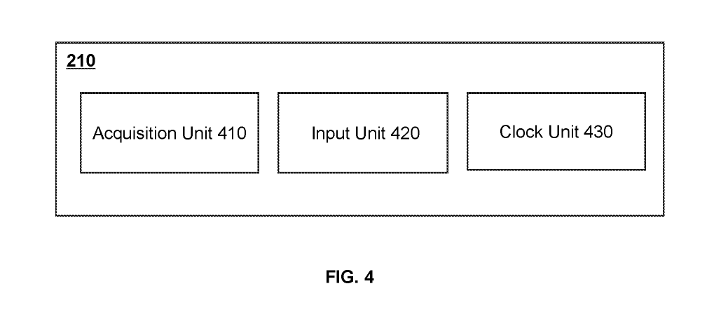

FIG. 4 is a schematic diagram of an acquisition module according to some embodiments of the present disclosure. The acquisition module 210 may include an acquisition unit 410, an input unit 420, and a clock unit 430. The acquisition unit 410 may obtain one or more external signals. In some embodiments, the external signals may include circuit-related signals. The circuit-related signals may include one or more electrical parameters such as current, voltage, frequency, capacitance, noise, impedance, bias voltage, etc. In some embodiments, the current may be acquired by a Hall current sensor, a Rogowski coil, a fiber current sensor, an analog digital converter (ADC), etc. The voltage may be acquired by a voltmeter, an oscilloscope, a voltage transformer, a Hall voltage sensor, etc. In some embodiments, the acquisition unit 410 may also acquire environment-related signals, and send the environment-related signals to the processing module for feedback adjustment regarding the indoor environment. The environment-related signals may be obtained using sensors of different types, such as a temperature sensor, a humidity sensor, a brightness sensor, a sound sensor, etc.

In some embodiments, the acquisition unit 410 may have bidirectional communication with the processing module 220. For example, the acquisition unit 410 may receive instructions for acquiring signals from the processing module 220. After the required signals are acquired, the acquisition unit 410 may send the acquired signals to the processing module 220 for further processing. In some embodiments, the acquisition unit 410 may acquire the circuit-related signals using built-in detection elements, or external acquisition elements or devices. When the external acquisition elements or devices are used, connections between external acquisition elements or devices and the acquisition unit 410 may be wired connections, wireless connections, or a combination of both.

The input unit 420 may receive a request or data input by a user. In some embodiments, the input unit 420 may communicate with the processing module 220 bidirectionally. For example, the input unit 420 may receive an information acquisition instruction generated by the processing module 220 for acquiring input from a user, complete the request input by the user, and send the input information to the processing module 220 for processing. In some embodiments, the input unit 420 may also send the input information to a storage unit. In some embodiments, the request input by the user may include adjusting a circuit load of an electric circuit according to a quota, turning on/off one or more appliances, calculating target parameters, etc. The data input by the user may include a time for calculating an electric power, a unit price for calculating an electricity fee, a voltage value for calculating an effective power, etc. In some embodiments, the input unit 420 may be implemented on a smart terminal. The smart terminal may include a desktop computer, a mobile phone, a tablet computer, a laptop computer, a carputer, or the like. In some embodiments, the input unit 420 may obtain information from a user through a mouse operation, a handwriting operation, a touching screen operation, a gesture operation, a voice controlling operation, an eye contacting operation, or the like.

The clock unit 430 may provide time for the acquisition module 210. In some embodiments, the clock unit 430 may provide time to a user through the display module 230. In some embodiments, the clock unit 430 may include an integrated circuit timer, a software timer, or the like. In some embodiments, the clock unit 430 may be integrated into the hardware of the system in the form of an integrated circuit. In some embodiments, the clock unit 430 may include components external to the hardware of the system. For example, the clock unit 430 may be a software simulated timer connected to the system via a network. The clock unit 430 may include a calibration unit for calibrating time.

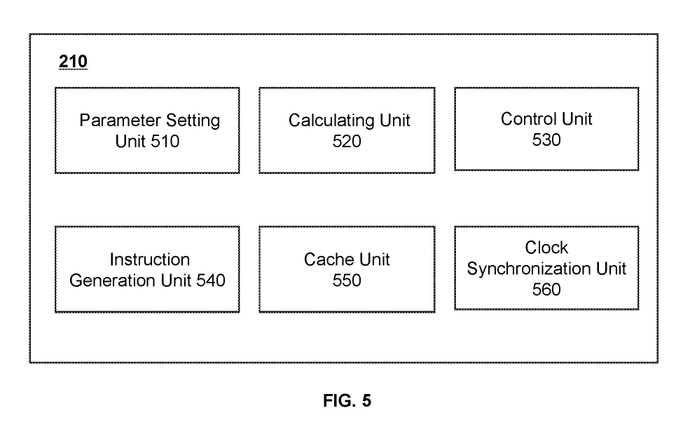

FIG. 5 is a schematic diagram of a processing module according to some embodiments of the present disclosure. The processing module 220 may include a parameter setting unit 510, a calculating unit 520, a control unit 530, an instruction generation unit 540, a cache unit 550, and a clock synchronization unit 560.

The parameter setting unit 510 may store and set parameters or thresholds that the circuit control terminal 110 may use for numerical calculation or logical processing. Further, the parameter setting unit 510 may store or set electrical circuit parameters or external environment parameters. Parameters stored or set by the parameter setting unit 510 may include but not limited to, a voltage amplitude, an effective voltage value, a current amplitude, an acquisition time, an acquisition frequency, a temperature, a humidity, a brightness, noise, and so on. In some embodiments, the parameter setting unit 510 may obtain input from the acquisition module 210 and/or adjust the parameters according to an algorithm adaptively. In some embodiments, the parameter setting unit 510 may obtain one or more parameter values, such as a voltage amplitude, a temperature threshold, etc., by requesting a user's input through the input unit 420. The parameter setting unit 510 may include storage, such as a register, a ROM, or a RAM. In some embodiments, the parameter setting unit 510 may store the parameter or threshold in the cache unit 550 or the storage module 240.

The calculating unit 520 may facilitate numerical calculation for the system. In some embodiments, the calculating unit 520 may perform numerical calculations on signals of external circuits and environmental parameters obtained from the parameter setting unit 510, the acquisition unit 410, the input unit 420, the cache unit 550, or the storage module 240. Values used for the numerical calculations may include electrical parameter values, such as a voltage amplitude, an effective voltage value, a current amplitude, a current value, noise, an impedance, and a bias voltage, time parameter values such as a year, a month, a day, an hour, a second, etc., and dimensionless parameters, such as the count of acquisition times, percentage, multiple, etc. Exemplary numerical calculation methods may include wavelet transform, principal component analysis, factor analysis, digital-to-analog conversion, analog-to-digital conversion, low-pass filtering, numerical fitting, etc. In some embodiments, the calculating unit 520 may be a processing element capable of computation, such as a multiplier. In some embodiments, the calculating unit 520 may be a stand-alone computing device, such as a calculator, a desktop computer, a tablet computer, a server, a supercomputer, etc.

The control unit 530 may make logical judgments and/or control determinations based on numerical parameters or instructions, and generate corresponding control information. In some embodiments, the control unit 530 may process data obtained from the calculating unit 520, data obtained by the acquisition unit 410, or numerical parameters such as preset conditions of the parameter setting unit 510, and generate control information. In some embodiments, the control unit 530 may also generate control information according to an operation instruction including acquiring a signal, calculating a target parameter, displaying a statistical result, adjusting circuit loads, or the like. The control information may be converted into an executable instruction by the instruction generation unit 540 to implement the control of the circuit management system 100 or an external electric circuit. In some embodiments, the control unit 530 may be a programmable logic device (PLD), an application specific integrated circuit (ASIC), a processor (central processing unit, CPU), a system chip (system on chip, SoC), etc.

The instruction generation unit 540 may generate executable instructions based on the control information generated by the control unit. The executable instructions may include operation information, address information, etc. The operation information may indicate an approach and function of the operation. The address information may direct to an object associated with the operation. In some embodiments, the instructions generated by the instruction generation unit 540 may be transmitted to the acquisition module 210, thereby controlling the acquisition of information regarding the circuit or information input by a user. In some embodiments, the generated instructions may also be fed back to the processing module 220 for further calculation or logical processing so as to generate further instructions. In some embodiments, the instructions may be provided to the display module 230 to control information to be displayed and a manner in which the information is displayed. In some embodiments, the instructions may also be transmitted to the storage module 240 to control the storage and retrieval of the information. In some embodiments, the instructions may be output to a load device in a control circuit external to the circuit management system 100. In some embodiments, the instructions generated by the instruction generation unit 540 may include numerical operation instructions, logical determination instructions, hardware operation instructions, or the like. The numerical operation instructions may control the calculating unit 520 to perform corresponding numerical operations, for example, calculating amplification factors of the current and voltage in the circuit. The logical determination instructions may utilize the control unit to make a logical judgment and make an analytical determination, for example, generating a determination instruction associated with an on-off of the air conditioner based on an indoor temperature. The hardware operation instructions may control an on-off of hardware, a switch of function modes, etc., through firmware, for example, turning on lights based on an instruction for turning on the lighting system.

The cache unit 550 may obtain, transfer, or temporarily store data or instructions. The cache unit 550 may obtain information to be processed from the acquisition module 210 or the storage module 240. The processed information may be written to the cache unit 550, and sent to the display module 230 or the storage module 240. In some embodiments, intermediate data generated during a calculation process, data with higher priority, and frequently used data may also be stored in the cache unit 550. Content stored in the cache unit 550 may be pre-processed or unprocessed information obtained from the acquisition module 210, temporary information or information related to intermediate steps generated by the calculating unit 520, the control unit 530, or the instruction generation unit 540 of the processing module, frequently used information or information with higher priority in the storage module 240. In some embodiments, the cache unit 550 may include a plurality of caches, such as a level-three cache, a level-two cache, or a level-one cache. The level-one cache may further include a data cache and an instruction cache. In some embodiments, the cache unit may be a static random access memory (SRAM), a random access memory (RAM), etc., or other storage media that may be read and/or written, such as a hard disk, a read only memory (ROM), a flash memory, etc.

The clock synchronization unit 560 may provide time to the calculating unit 520. The clock synchronization unit 560 may synchronize with the clock unit 430 through a synchronization function. In some embodiments, when the clock synchronization unit 560 is synchronized with the clock unit 430, the acquisition module 210 may use the time provided by the clock unit 430 to acquire an instantaneous current value at a preset time, such as T₁, and output the instantaneous current value to the processing module 220. The processing module 220 may use the time provided by the clock synchronization unit 560 to complete the calculation of an electric power value Pi before a specified time T2. In some embodiments, the clock synchronization unit 560 and the clock unit 430 may constitute a clock module for providing clock synchronization for the acquisition module 210 and the processing module 220. In some embodiments, the clock synchronization unit 560 may be synchronized with the clock unit 430 through a synchronous circuit.

The above description of the processing module may be specific embodiments and should not be considered as the only feasible solution. It is obvious that for those skilled in the art, after understanding the basic principles of the processing module, multiple variations and modifications on implementation manners and steps of the processing module may be made without departing from the principles. For example, the parameter setting unit 510 may be included in the cache unit 550, and the clock synchronization unit 560 and the clock unit 430 may constitute a clock module included in the circuit control terminal 110. As another example, the instruction generation unit 540 may be included in the control unit 530, and generate instructions based on the determinations of the control unit 530. As a further example, a plurality of calculating units 520 and/or control units 530 may also be contemplated to execute different computations and control instructions simultaneously. However, these variations and modifications are still within the scope of the present disclosure.

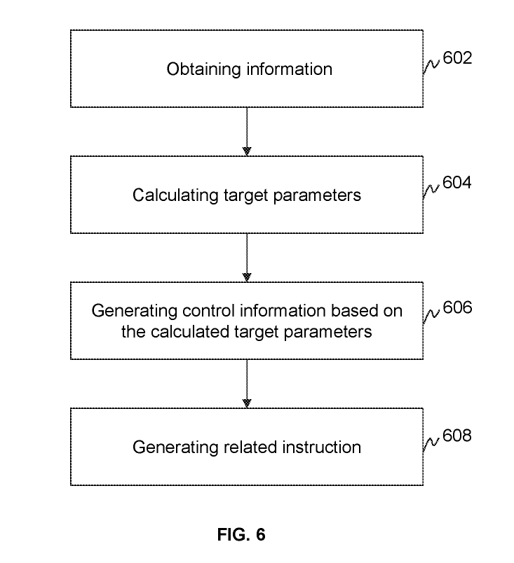

FIG. 6 is a flowchart of an exemplary process for processing obtained information and generating a control instruction according to some embodiments of the present disclosure. In 602, information may be obtained. The information may include electrical parameter data of load devices in an electrical circuit and parameters input by a user. The parameter input by the user may include but is not limited to electrical parameter values, such as a voltage amplitude, an effective voltage value, a current amplitude, a current value, noise, an impedance, and a bias voltage, time parameter values such as a year, a month, a day, an hour, a second, etc., and dimensionless parameters, such as the count of acquisition times, percentage, multiple, etc.

After data of an external circuit is obtained, the obtained data may be analyzed and/or calculated in 604. The analysis and/or calculation may include classification, noise reduction, analog-to-digital conversion, fitting, normalization, integration, discretization, and wavelet transform. Values of target parameters such as an amplification factor, a circuit impedance, an active power, a power factor, and a total power consumption may be obtained through the analysis and/or calculation. In some embodiments, the process for calculating the target parameters may be completed within a specified time period in combination with the clock synchronization unit.

In 606, the processed data may be retrieved and analyzed. Logical judgment and determination may be performed on the processed data so as to generate control information in combined with a user's instructions or preset conditions. In some embodiments, the logical judgment may include comparing the processed data with a threshold. In some embodiments, the threshold may be input by a user or based on a preset condition. If a target parameter is greater than the threshold, a set of control information may be executed; if the target parameter is less than the threshold, another set of control information may be performed. In some embodiments, the processing module 220 may obtain historical data in a historical period of time (e.g., last 24 hours), calculate a total power consumption of all of the load devices, and compare the total power consumption with the threshold. If the total power consumption is less than the threshold, control information for outputting the total power consumption to a user interface may be generated.

In 608, a control instruction may be generated based on the generated control information, and the control instruction may be transmitted to corresponding modules of the circuit management system 100 for execution. In some embodiments, the generated control instruction may control the display module to display the calculated results (e.g., an electric power) to the user. The manner in which the control instruction is displayed may include displaying the calculation results in the form of a statistical chart. Further, the manner in which the control instruction is displayed may also include an audio, an LED illumination, a mechanical vibration, or the like.

It should be noted that the above description is a specific process or steps for calculating external signals, and outputting and displaying the calculation results. A person having ordinary skills in the relevant art may make various variations and modifications on the modules and sequences of the steps, for example, the acquired external signals may be output and displayed directly without analyzing and computing in 604. However, these variations and modifications are still within the scope of the above description.

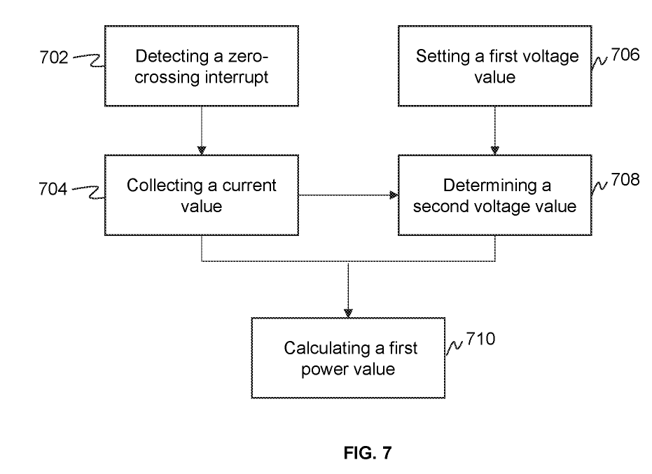

FIG. 7 is a flowchart of an exemplary process for calculating an instantaneous power according to some embodiments of the present disclosure. In some embodiment, the process for calculating the instantaneous power as illustrated in FIG. 7 may be used to calculate an electric power of an alternating current (AC) signal. The AC signal may include a sine wave, a square wave, etc., and the size and direction of the AC signal may change with time alternatively.

In 702, the circuit control terminal 110 may detect one or more zero-crossing interrupts. A zero-crossing interrupt may be a process in which an interrupt signal is generated when an electrical signal changes from −0 to +0 or from +0 to −0 in an AC system. In some embodiments, the zero-crossing interrupt may be measured by a zero-crossing interrupt circuit. The zero-crossing interrupt circuit may be integrated into the acquisition unit 410, other modules or sub-modules of the circuit management system 100, or an external electric circuit. In some embodiments, the circuit control terminal 110 may activate the clock synchronization unit and start timing from zero after a zero-crossing interrupt is detected.

In 704, the circuit control terminal 110 may acquire one or more current values. In some embodiments, the acquisition unit 410 in the circuit control terminal 110 may establish a one-to-one connection with load devices, and the acquisition unit 410 may acquire input current in each load device separately. In some embodiments, the acquisition unit 410 may establish a one-to-many connection with a plurality of load devices 130-1, 130-2, . . . , 130-N, and acquire a total current on input circuits of the load devices. The current value may be acquired by a Rogowski coil, a fiber optic current sensor, an analog to digital converter (ADC), or the like. In some embodiments, the circuit control terminal 110 may acquire current signals according to a preset minimum sampling time interval.

In 706, a first voltage value may be set. The first voltage value may be a standard value. In some embodiments, the first voltage value may be an effective voltage in an AC circuit. For example, in a 220V AC circuit, the first voltage value may be set to 220V. In some embodiments, the first voltage value may be a voltage amplitude. For example, the first voltage may be a voltage amplitude of an AC circuit processed according to a method such as smoothing, modulation, or rectification. In some embodiments, the first voltage value may be input by a user, or obtained by other means, such as via the server 150 or a parameter setting unit 510.

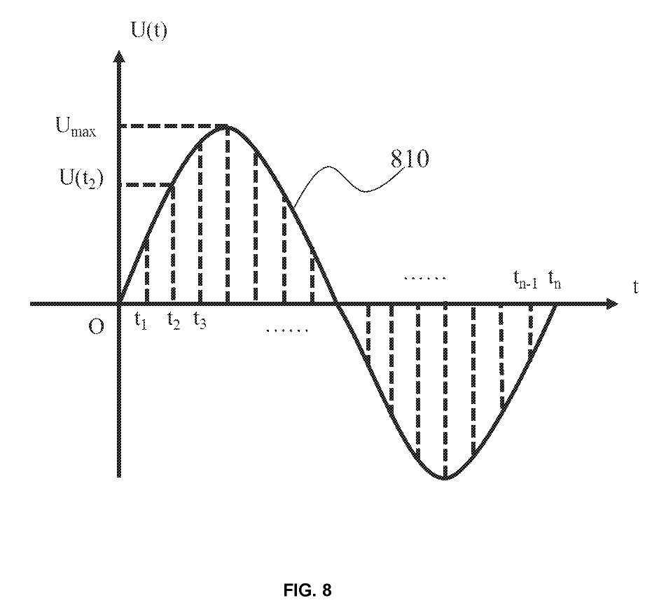

In 708, a second voltage value may be calculated based on the first voltage value and a current acquisition time. The second voltage value may be a voltage value corresponding to a certain time or phase angle of a given voltage waveform. Detailed descriptions regarding the calculation of the second voltage value may be described elsewhere, for example, FIG. 8 and the descriptions thereof.

FIG. 8 is a schematic diagram illustrating the calculation of an instantaneous voltage according to some embodiments of the present disclosure. As shown in FIG. 8, an AC voltage without filtering or modulating may have a sinusoidal waveform 810. Given a first voltage value U₀, at the time t or a phase angle

$$2 π \frac{t}{T} ,$$

the corresponding voltage value may be a second voltage value, which may be expressed as:

$$U ( t ) = {U}_{max} sin ( 2 π \frac{t}{T} ) , \qquad ( 1 )$$

where Uₘₐₓ=\sqrt{2}, T is a period or cycle of the sine wave. In some other embodiments, the AC voltage processed according to a method such as filtering, modulation, or rectification filtering or modulating may have a square waveform, a triangular waveform, etc. The processed waveform may be obtained using non-measurement methods. The second voltage value at the predetermined time or the phase angle may be calculated accordingly. For example, the waveform of the AC voltage processed according to a method such as the smoothing, modulating, rectifying may be estimated.

Returning to FIG. 7, in 704, when the zero-crossing detection circuit detects a zero-crossing interrupt, the circuit control terminal 110 may start acquiring current values at set time points. In some embodiments, the time point corresponding to the zero-crossing interrupt may be designated as a zero point. The current value may be acquired at a regular time interval starting from the zero point. For example, in a 50 Hz AC circuit, the cycle may be 0.02 seconds, the sampling count preset in the parameter setting unit 510 may be n, the time at the i-th sampling may be 0.02

$$\frac{i}{n} ,$$

and the corresponding phase angle in a cycle may be

$$2 π \frac{i}{n} .$$

In 708, phase angles at the time when the current values are acquired in the cycles may be obtained by setting the acquisition time of the current values, and the second voltage value may be calculated using the phase angles. For example, if the time when the current values are acquired corresponds to π/4 in cycles, the voltage values in the voltage waveform at π/4 in the cycles may be the second voltage value. In addition, acquisition times when the current values are acquired may also be obtained. By shifting the current waveform and/or the voltage waveform along a horizontal axis, the current waveform and the voltage waveform may be in a same phase. The second voltage value may be a voltage value in the voltage waveform sampled at corresponding time points of the acquisition time of the current values.

In some embodiments, the operations in 702 and 704 and the operations in 706 and 708 may be performed in parallel, and the operations in 706 and 708 may be performed before, after, or simultaneously with the operations in 702 and 704. In some embodiments, the circuit control terminal 110 may start acquiring the current values according to the clock synchronization unit and the preset time interval after the zero-crossing interrupt is detected. In some embodiments, the current acquisition time may be synchronous with the time when the second voltage value is calculated via the clock synchronization unit 560. In some embodiments, the time when the second voltage value is calculated may fall behind the current acquisition time. For example, the circuit control terminal 110 may start calculating the second voltage value after the current values are acquired. In some embodiments, the operations for calculating the second voltage value may be performed in the calculating unit 520.

In 710, instantaneous power values may be calculated. In some embodiments, the calculation of an instantaneous power value may include multiplying a current value acquired at a certain time by a corresponding second voltage value. In some embodiments, instantaneous power values may be calculated after all the current values are acquired, or an instantaneous power value at a moment may be calculated after a corresponding current value is acquired. In some embodiments, the calculation of the power values and the second voltage values may be performed by two different calculating units 520, respectively. The instantaneous power values may be expressed as:

Pₜ_{ᵢ}=Uₜ_{ᵢ}×Iₜ_{ᵢ}, (2)

where Pₜ_{ᵢ} denotes an instantaneous power value at time tᵢ, Uₜ_{ᵢ} denotes an instantaneous voltage value at time tᵢ, Iₜ_{ᵢ} denotes an instantaneous current value measured at time tᵢ.

The above description of the process for calculating of instantaneous power values may be specific embodiments and should not be considered as the only feasible solution. It is obvious that for those skilled in the art, after understanding the basic principles of the processing module, multiple variations and modifications on implementation manners and steps of the processing module may be made without departing from the principles. For example, in some embodiments, the circuit control terminal 110 may sample the current in a preset cycle. The circuit control terminal 110 may calculate the second voltage value corresponding to the phase angle before or after the current value is acquired, or calculate the second voltage value in real time corresponding to the current acquisition time.

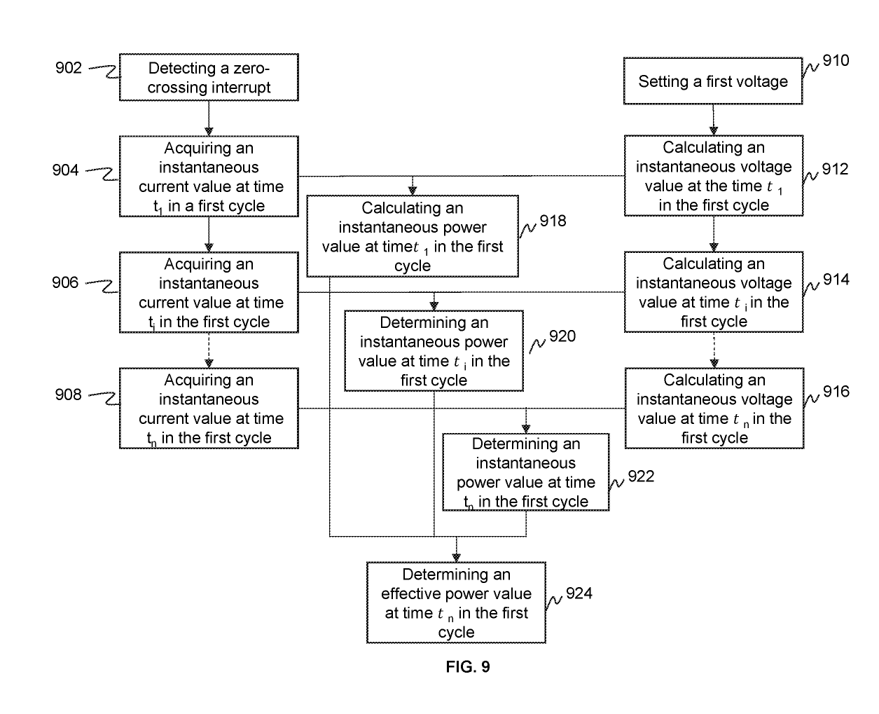

FIG. 9 is a flowchart of an exemplary process for calculating effective power in a cycle according to some embodiments of the present disclosure. According to the operations for calculating the instantaneous power values in FIG. 7, the circuit control terminal 110 may start timing after a zero-crossing interrupt is detected in 902, and acquire the current value at time t₁ in a first cycle in 904. The circuit control terminal 110 may receive a preset first voltage value U₀ in 910, and calculate a corresponding second voltage value Uₜ_{₁} according to the first voltage value and the current acquisition time or the phase angle in the corresponding cycle in 912. In 918, the instantaneous power value Pₜ_{₁} at time t₁ in the first cycle may be calculated. The circuit control terminal 110 may also acquire the current value at time t₂ in 906, and calculate the second voltage value Uₜ_{₂} corresponding to the current at time t₂ in 914. In 920, the instantaneous power value Pₜ_{₂} at time t₂ may be determined according to Equation (2). At the n-th sampling, the current value at time tₙ may be acquired in 908, and the second voltage value Uₜ_{ₙ} corresponding to the current at time tₙ may be calculated in 916. In 922, the instantaneous power value Pₜ_{ₙ} at time tₙ may be determined according to the Equation (2). After completing the calculation of the n instantaneous power values in the first cycle, the circuit control terminal 110 may calculate an effective power P₁ in the first cycle in 924. The effective power value in the first cycle may be obtained by summing all of the effective power values in the first cycle and determining an average value of the all of the effective power values. The effective power in the first cycle may be expressed as:

$${P}_{1} = \frac{( {Pt}_{1} + ⋯ + {Pt}_{i} + ⋯ + {Pt}_{n} )}{n} . \qquad ( 3 )$$

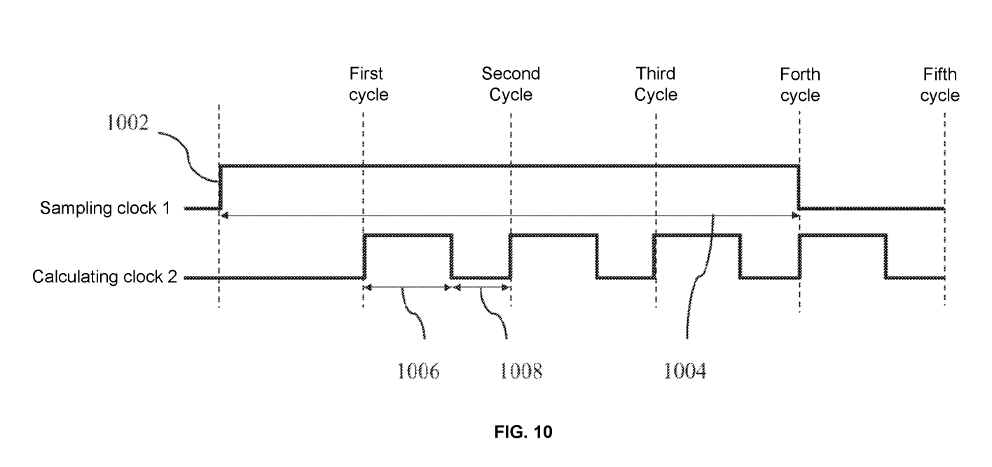

FIG. 10 is a schematic diagram illustrating operation sequences of an acquisition unit and a calculating unit according to some embodiments of the present disclosure. A sampling clock 1 may timing for the acquisition unit 410. In some embodiments, the sampling clock 1 may include the clock unit 430. In some embodiments, the acquisition unit 410 may start acquiring current values for calculating instantaneous power values after detecting a zero crossing. As shown in FIG. 10, the rising edge 1002 may correspond to a first time when the system detects a zero-crossing interrupt. The sampling clock 1 may be switched from a low level to a high level at the moment, and the acquisition unit 410 may start acquiring a current signal. As shown in FIG. 10, the acquisition time 1004 may be divided into four cycles, and the sampling clock 1 may be at a high level throughout the acquisition time, i.e., the acquisition unit 410 may be keep sampling throughout the acquisition time. In some embodiments, the current value acquired by the acquisition unit 410 may be stored in the cache unit 550.

A calculating clock 2 may provide timing information for the calculating unit 520. In some embodiments, the calculation clock 2 may be synchronized with the sampling clock 1 by the clock synchronization unit 560. In the first cycle, the calculating unit 520 may be unoccupied. In the second cycle, the calculating unit 520 may obtain the current signal acquired by the acquisition unit 410 in the first cycle, and complete the calculation of the effective power value of the first cycle within a calculation time 1006. In some embodiments, the operations for calculating the effective power value may be the same as the operations described in FIG. 7. During a remaining time 1008, the calculating unit 520 may be unoccupied, and the calculating clock 2 may be at a low level. In some embodiments, the calculating unit 520 may start a calculation in a next cycle after the acquisition unit 410 acquires a current signal.

It should be noted that the operation sequences of the acquisition unit 410 and the calculating unit 520 are not strictly limited. The calculating clock 2 may be switched to a high level at any time before the acquisition of the current values, and the calculation of the effective power of the cycle may be completed at any time after the current values are acquired. In some embodiments, the sampling clock 1 and the calculating clock 2 may be a same clock.

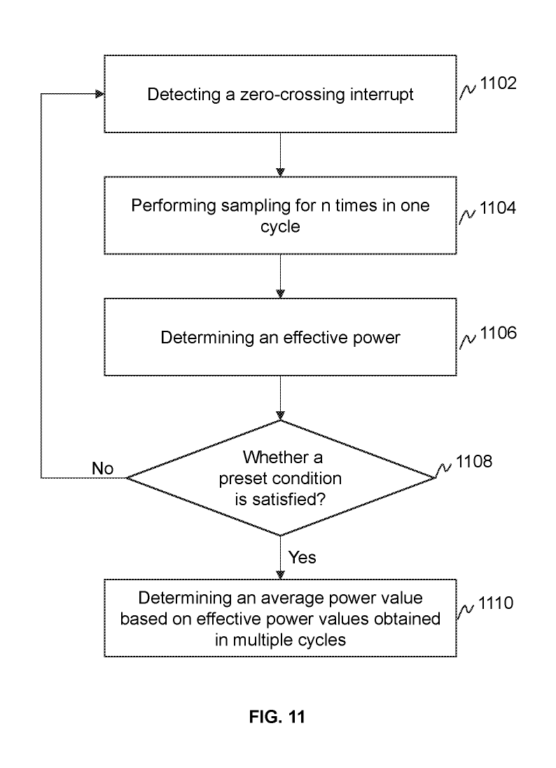

FIG. 11 is a flowchart of an exemplary process for calculating average power according to some embodiments of present disclosure. An effective power may be obtained in a cycle by performing operations in 1102, 1104, 1106, which are the same as the operations described in FIG. 9. In 1108, the circuit control terminal 110 may determine whether a preset condition is satisfied. Further, the circuit control terminal 110 may determine the count of cycles in which effective power values are calculated, and determine whether the count reaches a preset threshold. If the count does not reach the threshold, operations in 1102, 1104, 1106 may be repeated to calculate another effective power value of a next cycle until the count reaches the threshold. The circuit control terminal 110 may calculate an average power value P in 1110 based on effective power values obtained in multiple cycles. The average power value may be determined according to an algorithm for determining average values such as arithmetic averaging, weighted averaging, harmonic averaging, square averaging, or the like.

In some embodiments, the circuit control terminal 110 may calculate the average power value in a plurality of cycles by removing a maximum effective power value and a minimum effective power value, and determine an average value of the rest power values:

$$P = \frac{( {P}_{1} + ⋯ + {P}_{i} + ⋯ + {P}_{m} - {P}_{max} - {P}_{min} )}{m = 2} , \qquad ( 4 )$$

where m is the threshold, Pₘₐₓ is the maximum power value in the plurality of cycles, and Pₘᵢₙ is the minimum power value in the plurality of cycles.

In some embodiments, the circuit control terminal 110 may determine an average value of the effective power values in the plurality of cycles directly to calculate the average power value:

$$P = \frac{( {P}_{1} + ⋯ + {P}_{i} + ⋯ + {P}_{n} )}{m} , \qquad ( 5 )$$

where m is the threshold.

In some embodiments, a square of the average power value may be a mean value of the squares of the effective power values in the plurality of cycles:

$$P = \sqrt{\frac{{P}_{1}^{2} + ⋯ + {P}_{i}^{2} + ⋯ + {P}_{m}^{2}}{m}} . \qquad ( 6 )$$

It should be noted that the description above does not limit the form or operation steps of an average load power. It will be understood that those skilled in the art, after understanding the basic principles of the application, may perform multiple variations and modifications on the form and details of the operations and sequences of the calculation of the power values without departing from the principle. For example, the circuit control terminal 110 may calculate the average power in any time period instead of one or more whole cycles to calculate the effective power value or average power value of the load devices. However, these variations and modifications are still within the scope of the above description.

The basic concept has been described above, and it is obvious to those skilled in the art that the above disclosure is merely an example and does not constitute a limitation to the present disclosure. Various modifications, improvements, and alterations of the present disclosure may be made by those skilled in the art, although not explicitly stated herein. These alterations, improvements, and modifications are intended to be suggested by this disclosure, and are within the spirit and scope of the exemplary embodiments of this disclosure.

Moreover, certain terminology has been used to describe embodiments of the present disclosure. For example, the terms “one embodiment,” “an embodiment,” and/or “some embodiments” mean that a particular feature, structure or characteristic described in connection with the embodiment is included in at least one embodiment of the present disclosure. Therefore, it is emphasized and should be appreciated that two or more references to “an embodiment” or “one embodiment” or “an alternative embodiment” in various portions of this specification are not necessarily all referring to the same embodiment. Furthermore, the particular features, structures or characteristics may be combined as suitable in one or more embodiments of the present disclosure.

Further, it will be appreciated by one skilled in the art, aspects of the present disclosure may be illustrated and described herein in any of a number of patentable classes or context including any new and useful process, machine, manufacture, or composition of matter, or any new and useful improvement thereof. Accordingly, aspects of the present disclosure may be implemented entirely hardware, entirely software (including firmware, resident software, micro-code, etc.) or combining software and hardware implementation that may all generally be referred to herein as a “unit,” “module,” or “system.” Furthermore, aspects of the present disclosure may take the form of a computer program product embodied in one or more computer readable media having computer readable program code embodied thereon.

A computer readable signal medium may include a propagated data signal with computer readable program code embodied therein, for example, in baseband or as part of a carrier wave. Such a propagated signal may take any of a variety of forms, including electro-magnetic, optical, or the like, or any suitable combination thereof. A computer readable signal medium may be any computer readable medium that is not a computer readable storage medium and that may communicate, propagate, or transport a program for use by or in connection with an instruction execution system, apparatus, or device. Program code embodied on a computer readable signal medium may be transmitted using any appropriate medium, including wireless, wireline, optical fiber cable, RF, or the like, or any suitable combination of the foregoing.

Computer program code for carrying out operations for aspects of the present disclosure may be written in any combination of one or more programming languages, including an object oriented programming language such as Java, Scala, Smalltalk, Eiffel, JADE, Emerald, C++, C#, VB. NET, Python or the like, conventional procedural programming languages, such as the “C” programming language, Visual Basic, Fortran 2003, Perl, COBOL 2002, PHP, ABAP, dynamic programming languages such as Python, Ruby and Groovy, or other programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider) or in a cloud computing environment or offered as a service such as a Software as a Service (SaaS).

Furthermore, the recited order of processing elements or sequences, or the use of numbers, letters, or other designations therefore, is not intended to limit the claimed processes and methods to any order except as may be specified in the claims. Although the above disclosure discusses through various examples what is currently considered to be a variety of useful embodiments of the disclosure, it is to be understood that such detail is solely for that purpose, and that the appended claims are not limited to the disclosed embodiments, but, on the contrary, are intended to cover modifications and equivalent arrangements that are within the spirit and scope of the disclosed embodiments. For example, although the implementation of various components described above may be embodied in a hardware device, it may also be implemented as a software only solution, e.g., an installation on an existing server or mobile device.

Similarly, it should be appreciated that in the foregoing description of embodiments of the present disclosure, various features are sometimes grouped together in a single embodiment, figure, or description thereof for the purpose of streamlining the disclosure aiding in the understanding of one or more of the various embodiments. This method of disclosure, however, is not to be interpreted as reflecting an intention that the claimed subject matter requires more features than are expressly recited in each claim. Rather, claimed subject matter may lie in less than all features of a single foregoing disclosed embodiment.

In some embodiments, the numbers expressing quantities, properties, and so forth, used to describe and claim certain embodiments of the application are to be understood as being modified in some instances by the term “about,” “approximate,” or “substantially.” For example, “about,” “approximate,” or “substantially” may indicate ±20% variation of the value it describes, unless otherwise stated. Accordingly, in some embodiments, the numerical parameters set forth in the written description and attached claims are approximations that may vary depending upon the desired properties sought to be obtained by a particular embodiment. In some embodiments, the numerical parameters should be construed in light of the number of reported significant digits and by applying ordinary rounding techniques. Notwithstanding that the numerical ranges and parameters setting forth the broad scope of some embodiments of the application are approximations, the numerical values set forth in the specific examples are reported as precisely as practicable.

Each of the patents, patent applications, publications of patent applications, and other material, such as articles, books, specifications, publications, documents, things, and/or the like, referenced herein is hereby incorporated herein by this reference in its entirety for all purposes, excepting any prosecution file history associated with same, any of same that is inconsistent with or in conflict with the present document, or any of same that may have a limiting affect as to the broadest scope of the claims now or later associated with the present document. By way of example, should there be any inconsistency or conflict between the description, definition, and/or the use of a term associated with any of the incorporated material and that associated with the present document, the description, definition, and/or the use of the term in the present document shall prevail.

In closing, it is to be understood that the embodiments of the application disclosed herein are illustrative of the principles of the embodiments of the application. Other modifications that may be employed may be within the scope of the application. Thus, by way of example, but not of limitation, alternative configurations of the embodiments of the application may be utilized in accordance with the teachings herein. Accordingly, embodiments of the present application are not limited to that precisely as shown and described.

1. A method implemented on a device having at least one processor and at least one computer-readable storage medium, the method; comprising:
obtaining one or more current values;
setting a first voltage value;
determining one or more second voltage values based on the first voltage value, wherein the one or more second voltage values correspond to the one or more current values, respectively; and
generating one or more first power values according to the one or more current values and the one or more second voltage values.

2. The method of claim 1, wherein the one or more current values are obtained at one or more time points.

3. The method of claim 2, wherein intervals between the one or more time points are equal.

4. The method of claim 2, wherein the one or more second voltage values correspond to the one or more time points.

5. The method of claim 1, wherein the first voltage value is a standard value.

6. The method of claim 1, wherein the one or more first power values are products of the one or more current values and the corresponding one or more second voltage values, respectively.

7. The method of claim 1 further including:
generating a second power value based on the one or more first power values.

8. The method of claim 7, wherein the second power value is obtained based on the one or more first power values and an averaging algorithm.

9. A system, including:
an acquisition unit configured to obtain one or more current values;
an input unit configured to set a first voltage value;
a calculating unit configured to:
generate one or more second voltage values based on the first voltage value, wherein the one or more second voltage values correspond to the one or more current values, respectively; and
generate one or more first power values according to the one or more current values and the one or more second voltage values.

10. The system of claim 9, wherein the one or more current values are obtained at one or more time points.

11. The system of claim 10, wherein intervals between the one or more time points are equal.

12. The system of claim 10, the one or more second voltage values correspond to the one or more time points.

13. The system of claim 9, wherein the one or more first power values are products of the one or more current values and the one or more second voltage values, respectively.

14. The system of claim 9, the calculating unit further configured to generate a second power value based on the one or more first power values.

15. The system of claim 14, wherein the second power value is obtained based on one or more first power values and an averaging algorithm.

16. A computer readable storage medium storing executable instructions that cause a computer device to perform operations, the operations comprising:
obtaining one or more current values;
setting a first voltage value;
generating one or more second voltage values based on the first voltage value, wherein the one or more second voltage values correspond to the one or more current values, respectively; and
generating one or more first power values according to the one or more current values and the one or more second voltage values.

17. The computer readable storage medium of claim 16, wherein the one or more current values are obtained at one or more time points.

18. The computer readable storage medium of claim 17, wherein intervals between the one or more time points are equal.

19. The computer readable storage medium of claim 17, wherein the one or more second voltage values correspond to the one or more time points.

20. The computer readable storage medium of claim 16, wherein the one or more first power values are products of the one or more current values and the corresponding one or more second voltage values, respectively.
